(19) United States
(12) Patent Application Publication
(10) Pub. No.: US 2010/0164592 A1
(43) Pub. Date: Jul. 1, 2010

(54) LEVEL SHIFT CIRCUIT

(76) Inventors: Hak-Soo Kim, Cheongju-si (KR); Nam-Jin Song, Yongin-si (KR)

Correspondence Address: SHERR & VAUGHN, PLLC, 620 HERNDON PARKWAY, SUITE 320, HERNDON, VA, 20170, US

(21) Appl. No.: 12/640,973

(22) Filed: Dec. 17, 2009

(30) Foreign Application Priority Data
Dec. 31, 2008 (KR) 10-2008-0137771

(51) Int. Cl. H03L 5/00

(52) U.S. Cl. 327/333

(57) ABSTRACT

A level shift circuit. A level shift circuit may include a first voltage supply control unit connected to a first voltage terminal to control a supply of a first voltage via a first and/or second path according to statuses of first and/or second input signals inputted differentially, a second voltage supply control unit connected to a second voltage terminal to control a supply of a second voltage via a first and/or second path, a switching unit controlling a connection between first and second voltage supply control units on a first and/or second path, and/or a buffer unit outputting an output signal corresponding to a first voltage and/or a second voltage in response to a first potential outputted between a first voltage supply control unit and a switching unit and/or a second potential output between a second voltage supply control unit and a switching unit.

The present application claims priority under 35 U.S.C. 119 to Korean Patent Application No. 10-2008-0137771 (filed on Dec. 31, 2008) which is hereby incorporated by reference in its entirety.

### BACKGROUND

Embodiments relate to electrical circuits and methods thereof. Some embodiments relate to a level shift circuit and methods thereof.

A level shifter may be used to convert an input signal having a prescribed voltage level to a signal having another voltage level. A level shifter may convert an input signal of a relatively low voltage to an output signal of a relatively high voltage, and/or supply an output signal. A level shifter may convert an input signal of a relatively high voltage to an output signal of a relatively low voltage, and/or supply an output signal. Referring to example FIG. 1, a diagram of a level shift circuit is illustrated.

Referring to FIG. 1, a level shift circuit may include level shift unit 10 and/or buffer unit 12. Shift level shift unit 10 may include a plurality of PMOS transistors P1 to P4 and/or a plurality of NMOS transistors N1 to N4. A shift signal SH may be output which may correspond to power source voltage VDD according to level statuses of input signal IN, inverse input signal INB and/or ground voltage VSS. Input signal IN of a logic high level may be inputted to a gate of NMOS transistor N1 and/or an inverse input signal of a logic low level may be inputted to NMOS transistor N4, such that a PMOS transistor may be turned on and/or a potential corresponding to power source voltage VDD may be applied to a gate of NMOS transistor N2. NMOS transistor N2 may be turned on such that a potential corresponding to ground voltage VSS may be applied to a gate of PMOS transistor P4. PMOS transistor P4 may be turned on, such that shift signal SH having a potential corresponding to power source voltage VDD may be output. Inverse input signal INB of a logic low level may be input to NMOS transistor N4, such that PMOS transistors P and P3, and/or NMOS transistor N3, may remain turned off.

Buffer unit 12 may include PMOS transistor P5 which may receive shift signal SH in common and/or connected in series between a terminal of power voltage VDD and/or a terminal of ground voltage VSS. Buffer unit 12 may buffer shift signal SH, and/or output an output signal, such as output signal OUT. Shift signal SH of a logic high level may be output, such that output signal OUT having a potential corresponding to a level of ground voltage VSS may be output. Shift signal SH of logic low level may be output, such that output signal OUT having a potential corresponding to a level of power source voltage VDD may be output.

However, since shift signal SH may be applied to gates of PMOS and NMOS transistors P5 and N5 in buffer unit 12, a short-circuit current may be generated from a terminal of power source voltage VDD to a terminal of ground voltage VSS by PMOS and/or NMOS transistors P5 and/or N5 according to a level of shift signal SH. Therefore, electromagnetic interference (EMI) and the like may cause problems, for example a malfunction may be generated by ground bouncing attributed to a peak current.

Accordingly, there is a need of a level shift circuit and methods thereof which may minimize a peak value of a sort-circuit current, for example generated from buffering a level shifted voltage.

### SUMMARY

Embodiments relate to a level shift circuit and methods thereof. According to embodiments, a level shift circuit may minimize a peak value of a sort-circuit current, for example generated from buffering a level shifted voltage.

According to embodiments, a level shift circuit may include a first voltage supply control unit connected to a first voltage terminal, which may control a supply of a first voltage through a first and/or second path according to statuses of first and/or second input signals input differentially. In embodiments, a level shift circuit may include a second voltage supply control unit connected to a second voltage terminal, which may to control a supply of a second voltage through a first and/or second path. In embodiments, a level shift circuit may include a switching unit which may control a connection between first and second voltage supply control units on a first and/or second path. In embodiments, a level shift circuit may include a buffer unit which may output an output signal corresponding to a first voltage and/or a second voltage in response to a first potential output between a first voltage supply control unit and/or a switching unit, and/or a second potential output between a second voltage supply control unit and a switching unit.

According to embodiments, first voltage supply control unit may include a first transistor connected between a first switching unit and a first voltage terminal on a first path. In embodiments, a first transistor may have a gate to receive a first input signal. In embodiments, a first voltage supply control unit may include a second transistor connected between a first switching unit and a first voltage terminal on a second path. In embodiments, a second transistor may have a gate to receive a second input signal.

According to embodiments, a second voltage supply control unit may control a supply of a second voltage according to a presence and/or absence of a supply of a first voltage through a first voltage supply control unit. In embodiments, a second voltage supply control unit may include a first transistor connected between a second voltage terminal and a switching unit on a first path. In embodiments, a first transistor may have a gate connected to an output terminal of a first voltage supply control unit on a second path. In embodiments, a second voltage supply control unit may include a second transistor connected between a second voltage terminal and a switching unit on a second path. In embodiments, a second transistor may have a gate connected to an output terminal of a first voltage supply control unit on a first path.

According to embodiments, a second voltage supply control unit may control a supply of a second voltage according to statuses of first and/or second input signals. In embodiments, a second voltage supply control unit may include a first transistor connected between a second voltage terminal and a switching unit on a first path. In embodiments, a first transistor may have a gate to receive a first input signal. In embodiments, a second voltage supply control unit may include a second transistor connected between a second voltage terminal and a switching unit on a second path. In embodiments, a first transistor may have a gate to receive a second input signal.

According to embodiments, a switching unit may control a connection between first and second voltage supply units according to a presence and/or absence of a supply of a second voltage through a second voltage supply control unit. In embodiments, a switching unit may include a first transistor connected between first and second voltage supply control units on a first path. In embodiments, a first transistor may be controlled to be turned on according to a presence and/or absence of a supply of a second voltage on the first path through a second voltage supply control unit and/or a second transistor connected between first and second voltage supply control units on a second path. In embodiments, a second transistor may be controlled to be turned on according to a presence and/or absence a supply of a second voltage on a second path through a second voltage supply control unit.

According to embodiments, a switching unit may include a third transistor connected between a gate of a second transistor and a first voltage terminal. In embodiments, a third transistor may have a gate connected to an output terminal on a second path of a second voltage supply control unit. In embodiments, a switching unit may include a fourth transistor connected between a gate of a first transistor and a first voltage terminal. In embodiments, a fourth transistor may have a gate connected to an output terminal on a first path of a second voltage supply control unit.

According to embodiments, a switching unit may control a connection between first and second voltage supply units according to statuses of first and/or second input signals. According to embodiments, a switching unit may include a first transistor connected between first and second voltage supply control units on a first path. In embodiments, a first transistor may have a gate to receive a first input signal. In embodiments, a switching unit may include a second transistor connected between first and second voltage supply control units on a second path. In embodiments, a second transistor may have a gate to receive a second input signal.

According to embodiments, a switching unit may control a connection between first and second voltage supply units according to a presence and/or absence of a supply of a first voltage through a first voltage supply control unit. In embodiments, a switching unit may include a first transistor connected between first and second voltage supply control units on a first path. In embodiments, a first transistor may have a gate connected to an output terminal on a first path of a first voltage supply control unit. In embodiments, a switching unity may include a second transistor connected between first and second voltage supply control units on a second path. In embodiments, a second transistor may have a gate connected to an output terminal on a second path, of a first voltage supply control unit.

According to embodiments, a buffer unit may include a first transistor selectively supplying a first voltage as an output signal, which may include having a gate to receive a first potential output between a first voltage supply unit and a switching unit. In embodiments, a buffer unit may include a second transistor selectively supplying a second voltage as an output signal, which may include having a gate to receive a second potential output between a second voltage supply unit and a switching unit.

According to embodiments, a first voltage may correspond to a ground voltage and/or a second voltage may correspond to a power source voltage. In embodiments, a level shift circuit may buffer a signal in response to two signals output from a level shift unit with a time difference. In embodiments, a peak value of a short-circuit current may be minimized.

### DRAWINGS

FIG. 1 is a diagram illustrating a level shift circuit.

FIG. 2A to FIG. 2D are diagrams illustrating level shift circuits in accordance with embodiments.

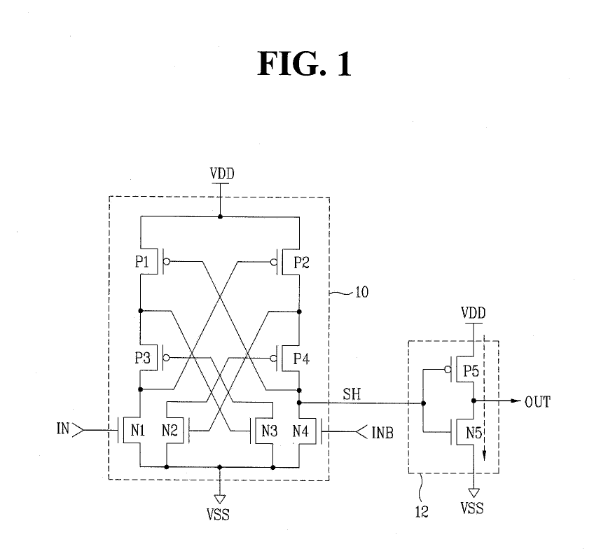

### DESCRIPTION

Embodiment relate to electrical circuits and methods thereof. According to embodiments, devices and/or methods may be suitable in a relatively wide scope of applications, including a buffer which may be configured to buffer a level-shifted voltage. In embodiments, a level shift circuit may include a level shift unit, a power source voltage supply control unit which may control a supply of power source voltage and/or a ground voltage supply control unit which may control a supply of a ground voltage. In embodiments, a level shift unit may receive an output of a power source voltage supply control unit and/or an output of a ground voltage control unit, and/or may buffers received outputs.

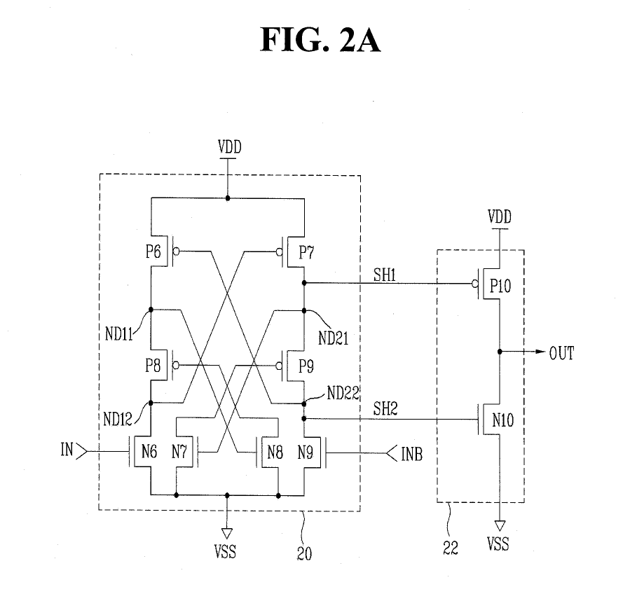

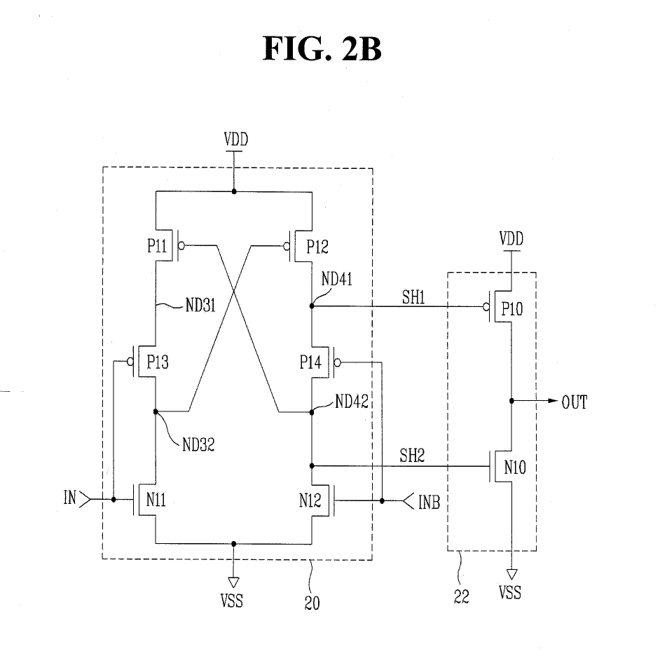

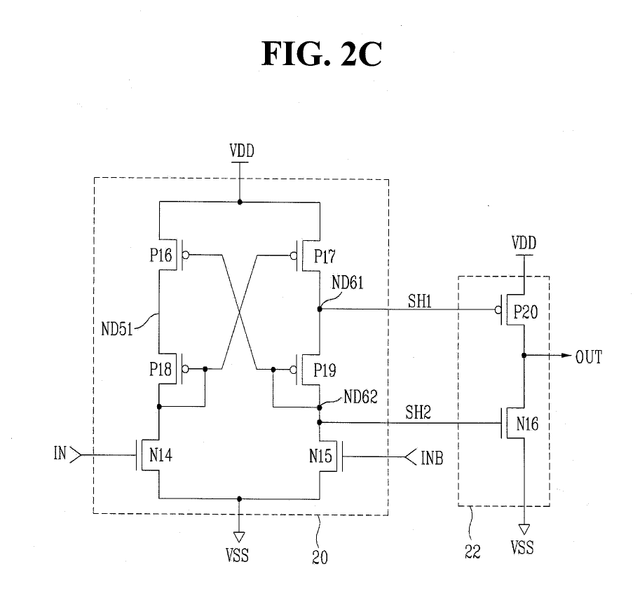

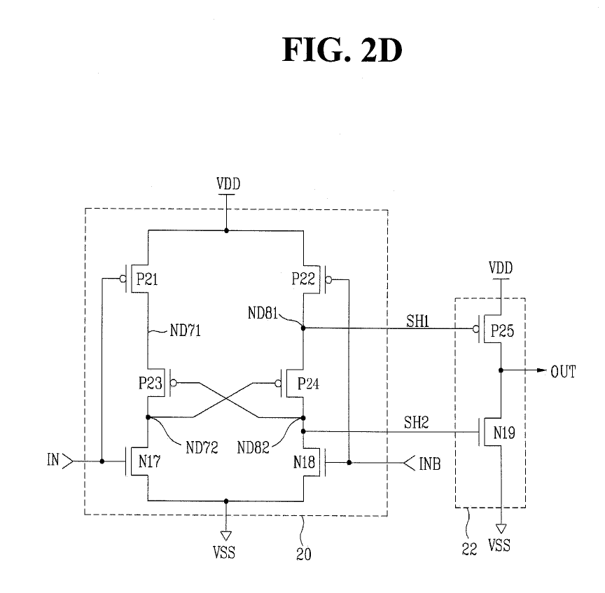

Referring to example FIGS. 2A to 2D, a level shift circuit in accordance with embodiments is illustrated. According to embodiments, a level shift circuit may include level shift unit 20 which may output shift signals SH1 and/or SH2, which may be in response to statuses of two differentially inputted input signals IN and/or INB. In embodiments, a level shift circuit may include buffer unit 22, which may output an output signal, such as output signal OUT, which may be in response to shift signals SH1 and/or SH2.

According to embodiments, level shift unit 20 may include a power source voltage supply unit which may include transistors to control a supply of a power source voltage. In embodiments, level shift unit 20 may include a ground voltage supply unit which may include transistors to control a supply of a ground voltage. In embodiments, level shift unit 20 may include a switching unit which may include transistors to control a connection between a power source voltage supply unit and a ground voltage supply unit.

Referring to FIG. 2A, a level shift circuit in accordance with embodiments is illustrated. According to embodiments, level shift unit 20 may include a power source voltage supply unit, a ground voltage supply unit having two NMOS transistors N6, N9, and/or a switching unit having two PMOS transistors P8, P9 and two NMOS transistors N7, N8. In embodiments, PMOS transistor P6 may be connected between a terminal of power source voltage VDD and node ND11. In embodiments, PMOS transistor P7 may be connected between a terminal of power source voltage VDD and node ND21. In embodiments, a gate of PMOS transistor P6 may be connected to node ND22. In embodiments, a gate of PMOS transistor P7 may be connected to node ND12. In embodiments, NMOS transistor N6 may be connected between node ND12 and a terminal of ground voltage VSS. In embodiments, NMOS transistor N9 may be connected between node ND22 and a terminal of ground voltage VSS. In embodiments, a gate of NMOS transistor N6 may receive input signal IN. In embodiments, a gate of NMOS transistor N9 may receive inverse input signal NB.

According to embodiments, PMOS transistor P8 may be connected between two nodes ND11, ND12. In embodiments, PMOS transistor P9 may be connected between two nodes ND21, ND22. In embodiments, NMOS transistor N7 may be connected between a gate of PMOS transistor P9 and a terminal of ground voltage VSS. In embodiments, NMOS transistor N8 may be connected between a gate of PMOS transistor P8 and a terminal of ground voltage VSS. In embodiments, a gate of NMOS transistor N7 may be connected to node ND 21. In embodiments, a gate of NMOS transistor N8 may be connected to node ND11.

According to embodiments, buffer unit 22 may include PMOS transistor P10, which may selectively supply power source voltage VDD to output signal OUT in response to shift signal SH1 output from node ND21. In embodiments, buffer unit 22 may include NMOS transistor N10, which may selectively supply ground voltage VSS to output signal OUT in response to shift signal SH2 output from node ND22. In embodiments, two differential input signals IN and INB may be input. In embodiments, PMOS transistor P10 and NMOS transistor N10 may not be substantially simultaneously turned on, for example as potentials of the two nodes ND21 and ND22 vary with a mutual time difference.

According to embodiments, a potential of logic high level may be input as an input signal IN and/or a potential of logic low level may be input as an inverse input signal NB, such that NMOS transistor N6 may be turned on and/or NMOS transistor N9 may be turned off. In embodiments, NMOS transistor N6 may be turned on, such that a potential corresponding to ground voltage VSS may be supplied to node ND12 which may turn on PMOS transistor P7. In embodiments, a potential corresponding to power source voltage VDD may be supplied to node ND21. In embodiments, shift signal SH1 may enters a logic high level, such that PMOS transistor P10 may be turned off.

According to embodiments, a potential corresponding to power source voltage VDD may be supplied to node ND21, such that NMOS transistor N7 may be turned on and/or potential corresponding to ground voltage VSS may be supplied to a gate of PMOS transistor P9. In embodiments, PMOS transistor P9 may be turned on such that a potential of node ND21 may be supplied to node ND22. In embodiments, shift signal SH2 may enter a logic high level, such that NMOS transistor N10 may be turned on and/or output an output signal OUT having a potential corresponding to ground voltage VSS. In embodiments, NMOS transistor N9 may be turned off by inverse input signal INB, such that when potential of node ND22 corresponds to power source voltage VDD, PMOS transistor P6, NMOS transistor N8 and/or PMOS transistor P8 may be turned off.

According to embodiments, a potential corresponding to power source voltage VDD may be supplied to two nodes ND21, ND22 sequentially in time. In embodiments, shift signal SH1 may have a potential corresponding to power source voltage VDD, and/or shift signal SH2 may then have a potential corresponding to power source voltage VDD. In embodiments, PMOS transistor P10 and NMOS transistor N10 may not be substantially simultaneously turned on and/or a substantially simultaneously turned-on time may be relatively shorter than a previous one. In embodiments, a peak value of a short-circuit current may be minimized that may flow from a terminal of a power source voltage VDD to a terminal of ground voltage VSS through PMOS transistor P10 and NMOS transistor N10.

Referring to FIG. 2B, a level shift circuit in accordance with embodiments is illustrated. According to embodiments, level shift unit 20 may include a power source voltage supply control unit having two PMOS transistor P11, P12, a ground voltage supply control unit having two NMOS transistors N11, N12, and a switching unit having two PMOS transistors P13, P14. In embodiments, PMOS transistor P11 may be connected between a terminal of power source voltage VDD and node ND31. In embodiments, PMOS transistor P12 may be connected between a terminal of power source voltage VDD and node ND41. In embodiments, a gate of PMOS transistor P11 may be connected to node ND42. In embodiments, a gate of PMOS transistor P12 may be connected to node ND32.

According to embodiments, NMOS transistor N11 may be connected between a terminal of ground voltage VSS and node ND32. In embodiments, NMOS transistor N12 may be connected between a terminal of ground voltage VSS and node ND42. In embodiments, a gate of NMOS transistor N11 may receive input signal IN and/or a gate of NMOS transistor N12 may receive inverse input signal INB. In embodiments, PMOS transistor P13 may be connected between two nodes ND31, ND32. In embodiments, PMOS transistor P14 may be connected between two nodes ND41, ND42. In embodiments, a gate of PMOS transistor P13 may receive input signal IN and/or a gate of PMOS transistor P14 may receive inverse input signal INB.

According to embodiments, buffer unit 22 may include PMOS transistor P15, which may selectively supply power source voltage VDD to output signal OUT in response to shift signal SH1 output from node ND41. In embodiments, NMOS transistor N13 may selectively supply ground voltage VSS to output signal OUT in response to shift signal SH2 output from node ND42. In embodiments, if input signal IN of logic high level is input and/or inverse input signal INB of logic low level is input, NMOS and PMOS transistors N11, P14, respectively, may be turned on and/or NMOS and PMOS transistors N12, P13, respectively, may be turned off. In embodiments, NMOS transistor N11 may be turned on, such that a potential corresponding to a ground voltage VSS may be supplied to node ND32 which may turn on PMOS transistor P12. In embodiments, PMOS transistor P12 may be turned on, such that a potential corresponding to power source voltage VDD may be supplied to node ND41. In embodiments, PMOS transistor P14 may be turned on, such that a potential of node ND41 may be supplied to node ND42. In embodiments, shift signal SH1 may enters logic high level, such that PMOS transistor P15 may be turned off. In embodiments, shift signal SH2 may enter a logic high level which may turn on NMOS transistor N13.

Referring to FIG. 2C, a level shift circuit in accordance with embodiments is illustrated. According to embodiments, level shift unit 20 may include a power source voltage supply control unit having two PMOS transistor P16, P17, a ground voltage supply control unit having two NMOS transistors N14, N15, and/or a switching unit having two PMOS transistors P18, P19. In embodiments, PMOS transistor P16 may be connected between a terminal of a power source voltage VDD and node ND51. In embodiments, PMOS transistor P17 may be connected between terminal of power source voltage VDD and node ND61. In embodiments, a gate of PMOS transistor P16 may be connected to node ND62. In embodiments, a gate of PMOS transistor P17 may be connected to node ND52.

According to embodiments, NMOS transistor N14 may be connected between a terminal of ground voltage VSS and node ND52. In embodiments, NMOS transistor N15 may be connected between a terminal of ground voltage VSS and node ND62. In embodiments, a gate of NMOS transistor N14 may receive input signal IN and/or a gate of NMOS transistor N15 may receive inverse input signal INB. In embodiments, PMOS transistor P18 may be connected between two nodes ND51, ND52. In embodiments, PMOS transistor P19 may be connected between two nodes ND61, ND62. In embodiments, a gate of PMOS transistor P18 may be connected to node ND52 and/or a gate of PMOS transistor 19 may be connected to gate node ND62.

According to embodiment, buffer unit 22 may include PMOS transistor P20, which may selectively supply power source voltage VDD to output signal OUT in response to shift signal SH1 output from node ND61. In embodiments, buffer unit 22 may include NMOS transistor N16, which may selectively supply ground voltage VSS to output signal OUT in response to shift signal SH2 output from node ND62. In embodiments, an input signal IN of logic high level may be input and inverse input signal INB of logic low level may be input, such that NMOS transistor N14 may be turned on and/or NMOS transistor N15 may be turned off. In embodiments, NMOS transistor N14 may be turned on, such that a potential corresponding to ground voltage VSS may be supplied to node ND52 which may turn on PMOS transistor P17. In embodiments, PMOS transistor P17 may be turned on, such that a potential corresponding to power source voltage VDD may be supplied to node ND61. In embodiments, PMOS transistor P17 may be turned on, such that a potential of node ND61 may be supplied to node ND62. In embodiments, shift signal SH1 may enter a logic high level, such that PMOS transistor P20 may be turned off. In embodiments, shift signal SH2 may enter a logic high level which may turn on NMOS transistor N16.

Referring to FIG. 2C, a level shift circuit in accordance with embodiments is illustrated. In embodiments, level shift unit 20 ma include a power source voltage supply control unit having two PMOS transistor P21, P22, a ground voltage supply control unit having two NMOS transistors N17, N18, and/or a switching unit having two PMOS transistors P23, P24. In embodiments, PMOS transistor P21 may be connected between a terminal of power source voltage VDD and node ND71. In embodiments, PMOS transistor P22 may be connected between a terminal of power source voltage VDD and node ND81. In embodiments, a gate of PMOS transistor P21 may receive input signal IN and/or a gate of PMOS transistor P22 may receive inverse input signal INB.

According to embodiments, NMOS transistor N17 may be connected between a terminal of a ground voltage VSS and node ND72. In embodiments, NMOS transistor N18 may be connected between a terminal of ground voltage VSS and node ND82. In embodiments, a gate of NMOS transistor N17 may receive input signal IN and/or a gate of NMOS transistor N18 may receive inverse input signal INB. In embodiments, PMOS transistor P23 may be connected between two nodes ND71, ND72. In embodiments, PMOS transistor P24 may be connected between two nodes ND81, ND82. In embodiments, a gate of PMOS transistor P23 may be connected to node ND82 and/or a gate of PMOS transistor P24 may be connected to node ND72.

According to embodiments, buffer unit 22 may include PMOS transistor P25, which may selectively supply power source voltage VDD to output signal OUT in response to shift signal SH1 output from node ND81. In embodiments, a buffer unit 22 may include NMOS transistor N19, which may selectively supply ground voltage VSS to output signal OUT in response to shift signal SH2 output from node ND82. In embodiments, input signal IN of logic high level may be input and/or inverse input signal INB of logic low level may be input, such that NMOS and/or PMOS transistors N17 and/or P22, respectively, may be turned on, and/or such that NMOS and/or PMOS transistors N18 and/or P21, respectively, may be turned off. In embodiments, PMOS transistor P22 may be turned on, such that a potential corresponding to power source voltage VDD may be supplied to node ND81. In embodiments, NMOS transistor N17 may be turned on, such that potential corresponding to ground voltage VSS may be supplied to node ND72. In embodiments, PMOS transistor P24 may be turned on, such that a potential of node ND81 may be supplied to node ND82. In embodiments, shift signal SH1 may enter a logic high level, such that PMOS transistor P25 may be turned off. In embodiments, shift signal SH2 may enter a logic high level, which may turn on NMOS transistor N19.

It will be obvious and apparent to those skilled in the art that various modifications and variations can be made in the embodiments disclosed. Thus, it is intended that the disclosed embodiments cover the obvious and apparent modifications and variations, provided that they are within the scope of the appended claims and their equivalents.

What is claimed is:

1. An apparatus comprising:
a first voltage supply control unit connected to a first voltage terminal configured to control a supply of a first voltage through at least one of a first path and a second path according to statuses of a first input signal and a second input signal;
a second voltage supply control unit connected to a second voltage terminal configured to control a supply of a second voltage through said at least one of said first path and said second path;
a switching unit configured to control a connection between said first voltage supply control unit and said second voltage supply control unit on said at least one of said first path and said second path; and
a buffer unit configured to output an output signal corresponding to at least one of said first voltage and said second voltage in response to at least one of a first potential output between said first voltage supply control unit and said switching unit and a second potential output between said second voltage supply control unit and said switching unit.

2. The apparatus of claim 1, wherein said first voltage supply control unit comprises:
a first transistor connected between said first switching unit and said first voltage terminal on said first path, said first transistor including a gate to receive said first input signal; and
a second transistor connected between said first switching unit and said first voltage terminal on said second path, said second transistor including a gate to receive said second input signal.

3. The apparatus of claim 1, wherein said second voltage supply control unit is configured to control said supply of said second voltage according to at least one of a presence and an absence of said supply of said first voltage through said first voltage supply control unit.

4. The apparatus of claim 3, wherein said second voltage supply control unit comprises:
a first transistor connected between said second voltage terminal and said switching unit on said first path, said first transistor including a gate connected to an output terminal of said first voltage supply control unit on said second path; and
a second transistor connected between said second voltage terminal and said switching unit on said second path, said second transistor including a gate connected to an output terminal of said first voltage supply control unit on said first path.

5. The apparatus of claim 1, wherein said second voltage supply control unit is configured to control said supply of said second voltage according to said statuses of said first input signal and said second input signal.

6. The apparatus of claim 5, wherein said second voltage supply control unit comprises:
a first transistor connected between said second voltage terminal and said switching unit on said first path, said first transistor including a gate to receive said first input signal; and
a second transistor connected between said second voltage terminal and said switching unit on said second path, said first transistor including a gate to receive said second input signal.

7. The apparatus of claim 1, wherein said switching unit is configured to control a connection between said first voltage supply unit and said second voltage supply unit according to at least one of a presence and an absence of said supply of said second voltage through said second voltage supply control unit.

8. The apparatus of claim 7, wherein said switching unit comprises:
a first transistor connected between said first supply control unit and said second voltage supply control unit on said first path, said first transistor controlled to be turned on according to at least one of a presence and an absence of said supply of said second voltage on said first path through said second voltage supply control unit; and
a second transistor connected between said first voltage supply control unit and said second voltage supply control unit on said second path, said second transistor controlled to be turned on according to at least one of presence and an absence of said supply of said second voltage on said second path through said second voltage supply control unit.

9. The apparatus of claim 8, wherein said switching unit comprises:
a third transistor connected between a gate of said second transistor and said first voltage terminal, said third transistor including a gate connected to an output terminal on said second path of said second voltage supply control unit; and
a fourth transistor connected between a gate of said first transistor and said first voltage terminal, said fourth transistor including a gate connected to an output terminal on said first path of said second voltage supply control unit.

10. The apparatus of claim 1, wherein said switching unit is configured to control a connection between said first voltage supply control unit and said second voltage supply control unit according to statuses of said first input signal and said second input signal.

11. The apparatus of claim 10, wherein said switching unit comprises:
a first transistor connected between said first voltage supply control unit and said second voltage supply control unit on said first path, said first transistor including a gate to receive said first input signal; and
a second transistor connected between said first voltage supply control unit and said second voltage supply control unit on said second path, said second transistor including a gate to receive said second input signal.

12. The apparatus of claim 1, wherein said switching unit is configured to control a connection between said first voltage supply control unit and said second voltage supply unit according to at least one of a presence and an absence of said supply of said first voltage through said first voltage supply control unit.

13. The apparatus of claim 12, wherein said switching unit comprises:
a first transistor connected between said first voltage supply control unit and said second voltage supply control unit on said first path, said first transistor including a gate connected to an output terminal on said first path of said first voltage supply control unit; and
a second transistor connected between said first voltage supply control unit and second voltage supply control unit on said second path, said second transistor including a gate connected to an output terminal on said second path of said first voltage supply control unit.

14. The apparatus of claim 1, wherein said buffer unit comprises:
a first transistor configured to selectively supply said first voltage as said output signal comprising a gate to receive said first potential output between said first voltage supply unit and said switching unit; and
a second transistor configured to selectively supply said second voltage as an output signal comprising a gate to receive said second potential output between said second voltage supply unit and said switching unit.

15. The apparatus of claim 1, wherein said first voltage corresponds to a ground voltage and said second voltage corresponds to a power source voltage.

16. A method comprising:
forming a first voltage supply control unit connected to a first voltage terminal configured to control a supply of a first voltage through at least one of a first path and a second path according to statuses of a first input signal and a second input signal;
forming a second voltage supply control unit connected to a second voltage terminal configured to control a supply of a second voltage through said at least one of said first path and said second path;
forming a switching unit configured to control a connection between said first voltage supply control unit and said second voltage supply control unit on said at least one of said first path and said second path; and
forming a buffer unit configured to output an output signal corresponding to at least one of said first voltage and said second voltage in response to at least one of a first potential output between said first voltage supply control unit and said switching unit and a second potential output between said second voltage supply control unit and said switching unit.

17. The method of claim 16, wherein said second voltage supply control unit is configured to at least one of
control said supply of said second voltage according to at least one of a presence and an absence of said supply of said first voltage through said first voltage supply control unit; and
control said supply of said second voltage according to said statuses of said first input signal and said second input signal.

18. The method of claim 16, wherein said switching unit is configured to at least one of:
control a connection between said first voltage supply unit and said second voltage supply unit according to at least one of a presence and an absence of said supply of said second voltage through said second voltage supply control unit;
control a connection between said first voltage supply control unit and said second voltage supply control unit according to statuses of said first input signal and said second input signal; and
control a connection between said first voltage supply control unit and said second voltage supply unit according to at least one of a presence and an absence of said supply of said first voltage through said first voltage supply control unit.

19. The method of claim 16, wherein said buffer unit comprises:
a first transistor configured to selectively supply said first voltage as said output signal comprising a gate to receive said first potential output between said first voltage supply unit and said switching unit; and
a second transistor configured to selectively supply said second voltage as an output signal comprising a gate to receive said second potential output between said second voltage supply unit and said switching unit.

20. The method of claim 16, wherein said first voltage corresponds to a ground voltage and said second voltage corresponds to a power source voltage.
